(19) United States
(12) Patent Application Publication
(10) Pub. No.: US 2025/0212687 A1
(43) Pub. Date: Jun. 26, 2025

(54) THERMOELECTRIC CONVERSION MODULE AND PRODUCTION METHOD FOR SAME

(71) Applicant: LINTEC CORPORATION, Tokyo (JP)

(72) Inventors: Shigehiro HAYASHI, Fukuoka-shi, Fukuoka (JP); Kunihisa KATO, Warabi-shi, Saitama (JP); Mutsumi MASUMOTO, Beppu-shi, Oita (JP)

(73) Assignee: LINTEC CORPORATION, Tokyo (JP)

(21) Appl. No.: 18/848,557

(22) PCT Filed: Mar. 23, 2022
(86) PCT No.: PCT/JP2022/013591

§ 371 Date: Sep. 19, 2024

(51) Int. Cl. H10N 10/17; G01K 7/22; H10N 10/01

(52) U.S. Cl. CPC H10N 10/17; G01K 7/22; H10N 10/01

(57) ABSTRACT

Provided are a thinner thermoelectric conversion module in which a thermistor for temperature detection is embedded inside a substrate included in the thermoelectric conversion module, and a method for manufacturing the thermoelectric conversion module. The thermoelectric conversion module includes a first substrate having a first principal surface and a second principal surface opposite to the first principal surface, a second substrate having a third principal surface facing the second principal surface and a fourth principal surface opposite to the third principal surface, a first electrode provided on the second principal surface, a second electrode provided on the third principal surface, a P-type thermoelectric element layer and an N-type thermoelectric element layer sandwiched between the first electrode and the second electrode and arrayed along the second principal surface and the third principal surface, and a thermistor for temperature detection embedded inside the first substrate and/or the second substrate, and current-carrying electrodes that energize the thermistor are located on at least one of the first principal surface, the second principal surface, the third principal surface, or the fourth principal surface.

### TECHNICAL FIELD

The present invention relates to a thermoelectric conversion module and a method for manufacturing the same.

### BACKGROUND ART

Typically, one means for effectively utilizing energy is a device that directly inter-converts thermal energy and electrical energy using a thermoelectric conversion module having a thermoelectric effect such as a Seebeck effect or a Peltier effect.

As such a thermoelectric conversion module, usage of a so-called π-type thermoelectric conversion element is known. In a basic unit of the π-type thermoelectric conversion element, a pair of electrodes spaced apart from each other are provided on substrates; for example, a lower surface of a P-type thermoelectric element is provided on one electrode and a lower surface of an N-type thermoelectric element is provided on the other electrode, with the lower surfaces being spaced apart from each other, and upper surfaces of the P-type thermoelectric element and the N-type thermoelectric element are connected to the electrodes on the facing substrates. The π-type thermoelectric conversion element is typically made up of several of the basic units electrically connected in series and thermally connected in parallel inside both substrates.

Here, Patent Document 1 discloses embedding a temperature sensor in a plate attached on a thermoelectric conversion module. Patent Document 2 discloses the provision of temperature sensors inside a thermoelectric conversion module.

### CITATION LIST

### Patent Literature

Patent Document 1: JP 2002-305275 A
Patent Document 2: WO 2020/071036

### SUMMARY OF INVENTION

### Technical Problem

However, in the thermoelectric conversion module in Patent Document 1, the temperature sensor is merely embedded in the plate attached on the thermoelectric conversion module (Peltier module) in order to measure temperature of an optical device (e.g., a semiconductor laser) installed on the plate. No substantial consideration has been given to reducing the thickness of the thermoelectric conversion module including the temperature sensor.

The thermoelectric conversion module in Patent Document 2 includes the temperature sensors installed inside the module, but the temperature sensors are installed on substrates included in the module. Therefore, in practice, the temperature sensors, current-carrying electrodes to which the temperature sensors are connected, and the like occupy a large area, which hinders high integration of thermoelectric elements.

The present invention has been made in view of such circumstances, and an object thereof is to provide a highly integrated and thin thermoelectric conversion module in which a thermistor for temperature detection is embedded inside a substrate included in the thermoelectric conversion module, and a method for manufacturing the thermoelectric conversion module.

### Solution to Problem

As a result of intensive studies to solve the above problems, the present inventors have found that a thinner thermoelectric conversion module, which does not require mounting of a thermistor on a heat absorption side and/or a heat dissipation side of a known thermoelectric conversion module by bonding using a highly thermally conductive adhesive, solder, or the like, can be obtained by embedding a thermistor for temperature detection inside a first substrate and/or a second substrate included in the thermoelectric conversion module, and have completed the present invention.

That is, the present invention provides the following [1] to [7].

[1] A thermoelectric conversion module includes a first substrate having a first principal surface and a second principal surface opposite to the first principal surface, a second substrate having a third principal surface facing the second principal surface and a fourth principal surface opposite to the third principal surface, a first electrode provided on the second principal surface, a second electrode provided on the third principal surface, a P-type thermoelectric element layer and an N-type thermoelectric element layer sandwiched between the first electrode and the second electrode and arrayed along the second principal surface and the third principal surface, and a thermistor for temperature detection, the thermistor being embedded inside the first substrate and/or the second substrate, in which current-carrying electrodes configured to energize the thermistor are located on at least one of the first principal surface, the second principal surface, the third principal surface, or the fourth principal surface.

[2] The thermoelectric conversion module according to [1], further includes a first heat dissipation layer on the first principal surface of the first substrate, and a second heat dissipation layer on the fourth principal surface of the second substrate.

[3] The thermoelectric conversion module according to [1] or [2], in which the current-carrying electrodes are located on the first principal surface of the first substrate or the fourth principal surface of the second substrate, and are provided as a pair of electrodes spaced apart from each other.

[4] The thermoelectric conversion module according to [1] or [2], in which the thermistor and the current-carrying electrodes are connected along a thickness direction of the first substrate or the second substrate.

[5] The thermoelectric conversion module according to [1] or [2], in which the first substrate and the second substrate are made of insulating materials.

[6] A method for manufacturing a thermoelectric conversion module, the thermoelectric conversion module including a first substrate having a first principal surface and a second principal surface opposite to the first principal surface, a second substrate having a third principal surface facing the second principal surface and a fourth principal surface opposite to the third principal surface, a first electrode provided on the second principal surface, a second electrode provided on the third principal surface, a P-type thermoelectric element layer and an N-type thermoelectric element layer sandwiched between the first electrode and the second electrode and arrayed along the second principal surface and the third principal surface, and a thermistor for temperature detection, the thermistor being embedded inside the first substrate and/or the second substrate, in which current-carrying electrodes configured to energize the thermistor are located on at least one of the first principal surface, the second principal surface, the third principal surface, or the fourth principal surface, the method includes (M) electrically connecting the second electrode to the P-type thermoelectric element layer and the N-type thermoelectric element layer on the first electrode provided on the second principal surface of the first substrate using the second substrate including the second electrode provided on the third principal surface, or (N) electrically connecting the first electrode to the P-type thermoelectric element layer and the N-type thermoelectric element layer on the second electrode provided on the third principal surface of the second substrate using the first substrate including the first electrode provided on the second principal surface.

[7] The method for manufacturing a thermoelectric conversion module according to [6], in which (M) or (N) includes the following (S-1) to (S-3).
(S-1): providing a through-hole in the first substrate and/or the second substrate
(S-2): embedding the thermistor in the through-hole
(S-3): providing the current-carrying electrodes to which the thermistor is to be connected on the first substrate and/or the second substrate

### Advantageous Effects of Invention

According to the present invention, it is possible to provide a highly integrated and thin thermoelectric conversion module in which a thermistor for temperature detection is embedded inside a substrate included in the thermoelectric conversion module, and a method for manufacturing the thermoelectric conversion module.

### BRIEF DESCRIPTION OF DRAWINGS

FIG. 1 is a cross-sectional configuration view of a first embodiment of a thermoelectric conversion module according to the present invention.

FIG. 2 is a cross-sectional configuration view of a second embodiment of a thermoelectric conversion module according to the present invention.

FIG. 3 is an explanatory diagram illustrating an example of steps of a method for manufacturing a thermoelectric conversion module according to the present invention in the order of the steps.

### DESCRIPTION OF EMBODIMENTS

### Thermoelectric Conversion Module

A thermoelectric conversion module according to the present invention includes a first substrate having a first principal surface and a second principal surface opposite to the first principal surface, a second substrate having a third principal surface facing the second principal surface and a fourth principal surface opposite to the third principal surface, a first electrode provided on the second principal surface, a second electrode provided on the third principal surface, a P-type thermoelectric element layer and an N-type thermoelectric element layer sandwiched between the first electrode and the second electrode and arrayed along the second principal surface and the third principal surface, and a thermistor for temperature detection embedded inside the first substrate and/or the second substrate, in which current-carrying electrodes configured to energize the thermistor are located on at least one of the first principal surface, the second principal surface, the third principal surface, or the fourth principal surface.

In the thermoelectric conversion module according to the present invention, by embedding the thermistor for temperature detection inside the first substrate and/or the second substrate included in the thermoelectric conversion module, the thinner thermoelectric conversion module can be achieved without mounting the thermistor on a heat absorption side and/or a heat dissipation side of the thermoelectric conversion module by, for example, bonding using a highly thermally conductive adhesive, solder, or the like.

In addition, since the current-carrying electrodes that energize the thermistor can be located on at least one of the first principal surface, the second principal surface, the third principal surface, or the fourth principal surface above, below, or above and below the thermistor embedded inside the substrate, wiring lengths from terminal electrodes at both ends of the thermistor to the current-carrying electrodes can be shortened, and the area of the current-carrying electrodes can be reduced compared with the case of mounting the thermistor on the substrate.

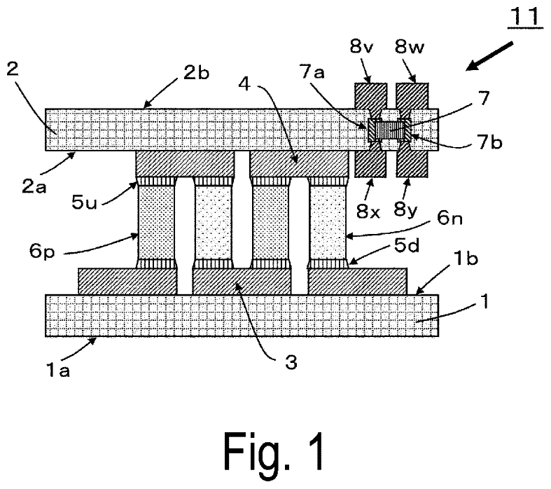

FIG. 1 is a cross-sectional configuration view illustrating a first embodiment of the thermoelectric conversion module according to the present invention. A thermoelectric conversion module 11 includes a first substrate 1 having a first principal surface 1a and a second principal surface 1b opposite to the first principal surface 1a, a second substrate 2 having a third principal surface 2a facing the second principal surface 1b and a fourth principal surface 2b opposite to the third principal surface 2a, a first electrode 3 provided on the second principal surface 1b, a second electrode 4 provided on the third principal surface 2a, a P-type thermoelectric element layer 6p and an N-type thermoelectric element layer 6n sandwiched between the first electrode 3 and the second electrode 4 and arrayed along the second principal surface 1b and the third principal surface 2a, and a thermistor 7 for temperature detection embedded inside the second substrate 2 and including a terminal electrode 7a and a terminal electrode 7b, in which a current-carrying electrode 8v and a current-carrying electrode 8w that energize the thermistor 7 are spaced apart from each other on the fourth principal surface 2b, and a current-carrying electrode 8x and a current-carrying electrode 8y that energize the thermistor 7 are spaced apart from each other on the third principal surface 2a. Note that upper surfaces of the P-type thermoelectric element layer 6p and the N-type thermoelectric element layer 6n are bonded to the second electrode 4 via solder layers 5u, and lower surfaces of the P-type thermoelectric element layer 6p and the N-type thermoelectric element layer 6n are bonded to the first electrode 3 via solder layers 5d.

In the first embodiment, since the thermistor 7 for temperature detection is embedded inside the second substrate 2, the thermistor does not need to be bonded to the fourth principal surface 2b (e.g., the heat absorption side) of the thermoelectric conversion module 11 using a highly thermally conductive adhesive, solder, or the like.

Further, since the current-carrying electrodes that energize the thermistor can be placed directly above and directly below the thermistor body embedded inside the substrate, wiring lengths from the terminal electrodes at both ends of the thermistor to the current-carrying electrodes can be shortened, and the area of the current-carrying electrodes can be reduced. Note that the substrate with the thermistor 7 embedded inside can be used on either the heat generation side or the heat absorption side, but it is preferable that the thermistor 7 be placed on the side where the temperature of the object is controlled (e.g., the heat absorption side). This makes it possible to sensitively catch heat conduction from the object and perform fine heat absorption and heat generation actions on the object with a quick response.

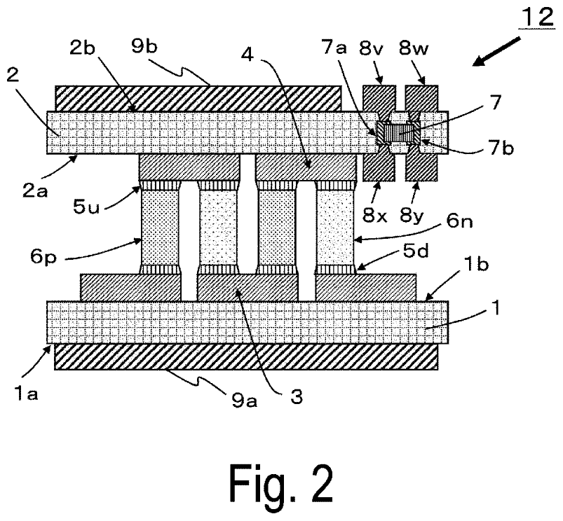

FIG. 2 is a cross-sectional configuration view illustrating a second embodiment of the thermoelectric conversion module according to the present invention. A thermoelectric conversion module 12 has a configuration in which a heat dissipation layer 9a is further provided on the first principal surface 1a and a heat dissipation layer 9b is further provided on the fourth principal surface 2b in the configuration in FIG. 1.

Also in the present embodiment, as in the first embodiment, since the thermistor 7 for temperature detection is embedded inside the second substrate 2, the thermistor does not need to be bonded to the fourth principal surface 2b (e.g., the heat absorption side) of the thermoelectric conversion module 11 using a highly thermally conductive adhesive, solder, or the like.

Further, since the current-carrying electrodes that energize the thermistor can be placed directly above and directly below the thermistor body embedded inside the substrate, wiring lengths from the terminal electrodes at both ends of the thermistor to the current-carrying electrodes can be shortened, and the area of the current-carrying electrodes can be reduced.

### Substrate

The thermoelectric conversion module according to the present invention includes the first substrate and the second substrate.

The thermistor for temperature detection is provided inside the first substrate and/or the second substrate. The first substrate and the second substrate function as supports for the P-type thermoelectric element layer and the N-type thermoelectric element layer.

The first substrate and the second substrate used in the present invention are preferably made of insulating materials. Examples of the insulating material include known substrates such as glass substrates, ceramic substrates, and resin substrates.

Alternatively, a lead frame, copper clad laminate (CCL), or the like may be used.

Examples of the ceramic substrate include materials containing aluminum oxide (alumina), aluminum nitride, zirconium oxide (zirconia), silicon carbide, or the like as a main component (50 mass % or more in the ceramic). In addition to the main component, for example, a rare earth compound can be added.

As the resin substrate, a heat-resistant resin substrate (film) is preferable from the viewpoint of easy processing, excellent flexibility, and high heat resistance and dimensional stability.

The heat-resistant resin substrate (film) has sufficient heat resistance that enables to retain a shape thereof even in high-temperature environments. To be specific, the heat-resistant resin substrate (film) has a melting point exceeding 130° C. or has no melting point, and has a thermal contraction coefficient of −1 to +1% when heated at 130° C. for 2 hours. The heat-resistant resin substrate (film) more preferably has a melting point of 140° C. or higher, or has no melting point, and particularly preferably has a melting point of 200° C. or higher, or has no melting point. By using such a substrate (film) having excellent heat resistance, it is possible to manufacture a thermoelectric conversion module having excellent dimensional accuracy even after a high-temperature manufacturing process such as bonding of a thermoelectric element layer and an electrode.

Here, the thermal contraction coefficient is defined as follows.

Thermal contraction coefficient (%)={(area of heat-resistant film before feeding)−(area of heat-resistant film after feeding)}/(area of heat-resistant film before feeding)×100

Examples of the heat-resistant resin substrate (film) include polyester films, polycarbonate films, polyphenylene sulfide films, cycloolefin resin films, polyimide resin films, films obtained by casting and curing a UV curable resin, and laminates of two or more types of these films. The cycloolefin resin film and the polyimide resin film may be mono-axially oriented or biaxially oriented.

The thicknesses of the first substrate and the second substrate are from 10 to 3000 μm, more preferably from 100 to 1000 μm, and particularly preferably from 150 to 600 μm, independently from the thickness of the thermistor for temperature detection, heat resistance, and dimensional stability.

### Thermistor

In the present invention, thermistors are used for detecting the temperature of the first substrate and the temperature of the second substrate. Since the thermistors are embedded inside the first substrate and the second substrate, the thermistors are thinner than the first substrate and the second substrate.

Thermistors are not limited as long as they are thinner than the thicknesses of the first substrate and the second substrate, and a negative temperature coefficient (NTC) thermistor having a negative temperature coefficient, a positive temperature coefficient (PTC) thermistor having a positive temperature coefficient, or the like can be used.

Among them, it is preferable to use the NTC thermistor, which is suitable for use in detecting and controlling temperature as a value, because a resistance value of the NTC thermistor changes uniformly and smoothly over a wide temperature range. Further, it is more preferable to use a chip-type NTC thermistor from the viewpoint that it can be made smaller, lighter, and thinner.

Examples of a material constituting the NTC thermistor include ceramics obtained by sintering oxides containing manganese (Mn), nickel (Ni), cobalt (Co), and the like.

Examples of commercially available thin NTC thermistors include the following.
NTC thermistor (manufactured by Mitsubishi Materials Corporation, model name: “VH05-6D103F”, 0.21 mm (length)×0.21 mm (width)×0.20 mm (thickness))
NTC thermistor (manufactured by Mitsubishi Materials Corporation, model name: “TZ05-3H103D”, 1.0 mm (length)×0.50 mm (width)×0.55 mm (thickness))
NTC thermistor (manufactured by Murata Manufacturing Co., Ltd., model name: “NCP02WF104F05RH”, 0.4 mm (length)×0.2 mm (width)×0.2 mm (thickness))

### Current-Carrying Electrode

The thermoelectric conversion module according to the present invention includes the current-carrying electrodes that energize the thermistor.

The current-carrying electrodes are preferably located on the first principal surface of the first substrate or the fourth principal surface of the second substrate and are provided as a pair of electrodes spaced apart from each other.

The current-carrying electrodes are wired, for example, to the terminal electrodes provided at both ends of the thermistor embedded inside the first substrate and/or the second substrate.

The thermistor and the current-carrying electrodes are preferably connected along the thickness direction of the first substrate or the second substrate.

In FIG. 1, for example, the current-carrying electrode 8v and the current-carrying electrode 8w are provided spaced apart from each other on the fourth principal surface 2b, and are simultaneously wired, for example, by electroplating, to the terminal electrode 7a and the terminal electrode 7b provided at both ends of the thermistor 7 embedded inside the second substrate. Similarly, the current-carrying electrode 8x and the current-carrying electrode 8y are provided spaced apart from each other on the third principal surface 2a, and are simultaneously wired, for example, by electroplating, to the terminal electrode 7a and the terminal electrode 7b provided at both ends of the thermistor 7 embedded inside the second substrate.

Thus, by providing the current-carrying electrodes on the substrate surface above, below, or above and below the thermistor, the wiring lengths can be made shorter compared with the case of mounting the thermistor on the substrate. In addition, by wiring with the terminal electrodes, for example, a four-terminal connection, which is a wiring method used to measure a resistance value of a thermistor used to accurately detect temperature changes, can be easily achieved, enabling highly accurate temperature control.

A metal material used for the current-carrying electrodes is not limited, and examples thereof include copper, gold, nickel, rhodium, platinum, palladium, and alloys thereof. Among them, copper is particularly preferable because it has low electric resistance, low material cost, and can be easily wired by plating, vapor deposition, or the like.

The thickness of the current-carrying electrodes is not limited as long as the resistance changes of the thermistor can be detected accurately. From the viewpoint of making the thermoelectric conversion module thinner, the thickness is preferably 3 to 500 μm, more preferably 5 to 300 μm, and particularly preferably 10 to 100 μm.

### Thermoelectric Element Layer

The thermoelectric element layer used in the present invention is not limited, and may be formed from a bulk thermoelectric semiconductor material or may be a thin film formed from a thermoelectric semiconductor composition.

From the perspectives of flexibility, thin profile, and thermoelectric performance, the thermoelectric element layer is preferably formed from a thin film formed from a thermoelectric semiconductor composition containing a thermoelectric semiconductor material (hereinafter, also referred to as “thermoelectric semiconductor particles”), a resin, and one or both of an ionic liquid and an inorganic ionic compound.

### Thermoelectric Semiconductor Material

The thermoelectric semiconductor material constituting the thermoelectric element layer is preferably pulverized to a predetermined size by, for example, a micropulverizer or the like, and used as thermoelectric semiconductor particles (hereinafter, the thermoelectric semiconductor material may be referred to as “thermoelectric semiconductor particles”).

The particle size of the thermoelectric semiconductor particles is preferably from 10 nm to 100 μm, more preferably from 30 nm to 30 μm.

The average particle size of the thermoelectric semiconductor particles was obtained by measurement using a laser diffraction particle size analyzer (Mastersizer 3000 available from Malvern Panalytical Ltd.), and the median of the particle size distribution is used as the average particle size.

The thermoelectric semiconductor material constituting the P-type thermoelectric element layer and the N-type thermoelectric element layer used in the present invention is not limited as long as the thermoelectric semiconductor material is a raw material that can generate thermoelectromotive force by providing a temperature difference. For example, bismuth-tellurium-based thermoelectric semiconductor materials such as P-type bismuth telluride and N-type bismuth telluride; telluride-based thermoelectric semiconductor materials such as GeTe and PbTe; antimony-tellurium-based thermoelectric semiconductor materials; zinc-antimony-based thermoelectric semiconductor materials such as ZnSb, Zn₃Sb₂, and Zn₄Sb₃; silicon-germanium-based thermoelectric semiconductor materials such as SiGe; bismuth selenide-based thermoelectric semiconductor materials such as Bi₂Se₃; silicide-based thermoelectric semiconductor materials such as β-FeSi₂, CrSi₂, MnSi_{1.73}, Mg₂Si; oxide-based thermoelectric semiconductor materials; Heusler materials such as FeVAl, FeVAlSi, and FeVTiAl; and sulfide-based thermoelectric semiconductor materials such as TiS₂ are used.

The content of the thermoelectric semiconductor particles in the thermoelectric semiconductor composition is preferably from 30 to 99 mass %. More preferably, the content is from 70 to 95 mass %. If the content of the thermoelectric semiconductor particles is within the range described above, the Seebeck coefficient (absolute value of the Peltier coefficient) is large, a decrease in electrical conductivity is suppressed, and only thermal conductivity is reduced, and therefore a film exhibiting a high thermoelectric performance and having sufficient film strength and flexibility is obtained. Thus, the content of the thermoelectric semiconductor particles is preferably within the range described above.

Furthermore, the thermoelectric semiconductor particles are preferably subjected to an annealing treatment (hereinafter, also referred to as an “annealing treatment A”). When the thermoelectric semiconductor particles are subjected to the annealing treatment A, the crystallinity of the thermoelectric semiconductor particles is improved, and a surface oxide film of the thermoelectric semiconductor particles is removed, and therefore the Seebeck coefficient (absolute value of the Peltier coefficient) of the thermoelectric element layer increases, and the thermoelectric performance index can be further improved.

### Resin

The resin used in the thermoelectric semiconductor composition has a function of physically bonding between the thermoelectric semiconductor materials (thermoelectric semiconductor particles), and can increase the flexibility of the thermoelectric conversion module and facilitate the formation of a thin film by coating or the like.

The resin is preferably a heat-resistant resin or a binder resin.

When crystal growth of the thermoelectric semiconductor particles is caused by subjecting the thin film formed from the thermoelectric semiconductor composition to an annealing treatment or the like, the physical properties such as mechanical strength and thermal conductivity of the heat-resistant resin as a resin are maintained without being impaired.

From the perspective of further increasing heat resistance and not adversely affecting crystal growth of the thermoelectric semiconductor particles in the thin film, the heat-resistant resin is preferably a polyamide resin, a polyamide-imide resin, a polyimide resin, or an epoxy resin, and from the perspective of excelling in flexibility, the heat-resistant resin is more preferably a polyamide resin, a polyamide-imide resin, or a polyimide resin.

The heat-resistant resin preferably has a decomposition temperature of 300° C. or higher. If the decomposition temperature is within the range described above, flexibility can be maintained without loss of function as a binder even when the thin film formed from the thermoelectric semiconductor composition is subjected to annealing treatment as described below.

The content of the heat-resistant resin in the thermoelectric semiconductor composition is preferably from 0.1 to 40 mass %, more preferably from 2 to 15 mass %. When the content of the heat-resistant resin is within the range described above, the heat-resistant resin functions as a binder of the thermoelectric semiconductor material and facilitates the formation of a thin film, a film having both high thermoelectric performance and film strength is obtained, and a resin portion is present on an outer surface of the chip of the thermoelectric conversion material.

The binder resin is a resin in which 90 mass % or more decomposes at the firing (annealing) temperature or higher, and is particularly preferably a resin in which 99 mass % or more decomposes at the firing temperature or higher.

When a resin in which 90 mass % or more decomposes at the firing (annealing) temperature or higher, that is, a resin that decomposes at a lower temperature than the heat-resistant resin described above, is used as the binder resin, the binder resin decomposes through firing, and therefore the content of the binder resin serving as an insulating component contained in the fired product is reduced, and crystal growth of the thermoelectric semiconductor particles in the thermoelectric semiconductor composition is promoted. Thus, voids in the thermoelectric element layer can be reduced, and the filling ratio can be improved.

Note that whether a resin decomposes at or above a predetermined amount (for example, 90 mass %) at or above the firing (annealing) temperature is determined by measuring the mass loss rate (a value obtained by dividing the mass after decomposition by the mass before decomposition) at the firing (annealing) temperature through thermogravimetry (TG).

A thermoplastic resin or a curable resin can be used as the binder resin. Examples of thermoplastic resin include polyolefin resins such as polyethylene, polypropylene, polyisobutylene, and polymethylpentene; polycarbonates; thermoplastic polyester resins such as polyethylene terephthalate and polyethylene naphthalate; polyvinyl polymers such as polystyrene, acrylonitrile-styrene copolymers, poly(vinylacetate), ethylene-vinyl acetate copolymers, vinyl chloride, poly(vinyl pyridine), poly(vinyl alcohol), and poly(vinyl pyrrolidone); polyurethanes; and cellulose derivatives such as ethyl cellulose. Examples of the curable resin include thermosetting resins and photocurable resins. Examples of thermosetting resins include epoxy resins and phenol resins. Examples of photocurable resins include photocurable acrylic resins, photocurable urethane resins, and photocurable epoxy resins. One of these may be used alone, or two or more may be used in combination.

The binder resin is appropriately selected according to the temperature of the firing (annealing) treatment of the thermoelectric semiconductor material in the firing (annealing) treatment process. The firing (annealing) treatment is preferably implemented at a temperature equal to or higher than the final decomposition temperature of the binder resin.

In the present specification, the “final decomposition temperature” refers to a temperature at which the mass loss rate at the firing (annealing) temperature as determined through thermogravimetry (TG) is 100% (mass after decomposition is 0% of the mass before decomposition).

The final decomposition temperature of the binder resin is typically from 150 to 600° C., preferably from 220 to 460° C. When a binder resin having a final decomposition temperature within this range is used, the binder resin functions as a binder for the thermoelectric semiconductor material, and formation of a thin film is facilitated when printing.

The content of the binder resin in the thermoelectric semiconductor composition is from 0.1 to 40 mass %, preferably from 0.5 to 10 mass %.

### Ionic Liquid

The ionic liquid that may be contained in the thermoelectric semiconductor composition is a molten salt obtained by combining a cation and an anion and is a salt that can be present as a liquid in any temperature region in −50° C. or higher and lower than 400° C. Because the ionic liquid has characteristics such as having a significantly low vapor pressure and being nonvolatile, having excellent thermal stability and electrochemical stability, having a low viscosity, and having a high ionic conductivity, the ionic liquid can effectively suppress reduction of the electrical conductivity between the thermoelectric semiconductor materials as a conductivity aid. Furthermore, because the ionic liquid exhibits high polarity based on the aprotic ionic structure and excellent compatibility with the heat-resistant resin is achieved, the electrical conductivity of the thermoelectric conversion material can be made uniform.

As the ionic liquid, a known or commercially available ionic liquid can be used. Examples thereof include those formed from nitrogen-containing cyclic cation compounds and derivatives thereof, such as pyridinium, pyrimidinium, pyrazolium, pyrrolidinium, piperidinium, and imidazolium; tetraalkylammonium-based amine cations and derivatives thereof; phosphine cations and derivatives thereof, such as phosphonium, trialkylsulfonium, and tetraalkylphosphonium; cation components, such as lithium cation and derivatives thereof; and anion components, such as Cl⁻, Br⁻, I⁻, AlCl₄⁻, Al₂Cl₇⁻, BF₄⁻, PF₆⁻, ClO₄⁻, NO₃⁻, CH₃COO⁻, CF₃COO⁻, CH₃SO₃⁻, CF₃SO₃⁻, (FSO₂)₂N⁻, (CF₃SO₂)₂N⁻, (CF₃SO₂)₃C⁻, AsF₆⁻, SbF₆⁻, NbF₆⁻, TaF₆⁻, F(HF)ₙ⁻, (CN)₂N⁻, C₄F₉SO₃⁻, (C₂F₅SO₂)₂N⁻, C₃F₇COO⁻, and (CF₃SO₂)(CF₃CO)N⁻.

Furthermore, the ionic liquid described above preferably has a decomposition temperature of 300° C. or higher. When the decomposition temperature is in the range described above, as described below, even in a case where a thin film formed from the thermoelectric semiconductor composition is subjected to annealing treatment, the effect as a conductivity aid can be maintained.

The content of the ionic liquid in the thermoelectric semiconductor composition is preferably from 0.01 to 50 mass %, more preferably from 1.0 to 20 mass %. When the content of the ionic liquid is in the range described above, reduction of the electrical conductivity is effectively suppressed, and a film having a high thermoelectric performance can be obtained.

### Inorganic Ionic Compound

The inorganic ionic compound that may be contained in the thermoelectric semiconductor composition is a compound formed from at least a cation and an anion. Because the inorganic ionic compound is present as a solid in a wide range of a temperature region, which is from 400 to 900° C., and has characteristics such as high ionic conductivity, the inorganic ionic compound can suppress reduction of the electrical conductivity between the thermoelectric semiconductor materials as a conductivity aid.

The content of the inorganic ionic compound in the thermoelectric semiconductor composition is preferably from 0.01 to 50 mass %, more preferably from 0.5 to 30 mass %. When the content of the inorganic ionic compound is in the range described above, reduction of the electrical conductivity is effectively suppressed and, as a result, a film having an improved thermoelectric performance can be obtained.

Note that, in a case where the inorganic ionic compound and the ionic liquid are used in combination, the total content of the inorganic ionic compound and the ionic liquid in the thermoelectric semiconductor composition is preferably from 0.01 to 50 mass %, more preferably from 0.5 to 30 mass %.

The method for preparing the thermoelectric semiconductor composition is not particularly limited, and the thermoelectric semiconductor composition can be prepared by, for example, adding the thermoelectric semiconductor particles, the ionic liquid, the inorganic ionic compound (when used in combination with the ionic liquid), the heat-resistant resin, and if necessary, the other additives and also a solvent, and mixing and dispersing the various components through a well-known method such as an ultrasonic homogenizer, a spiral mixer, a planetary mixer, a disperser, or a hybrid mixer.

Examples of the solvent include solvents such as toluene, ethyl acetate, methyl ethyl ketone, alcohol, tetrahydrofuran, methyl pyrrolidone, and ethyl cellosolve. One type of these solvents may be used alone, or two or more types of these solvents may be mixed and used. As the solid content concentration of the thermoelectric semiconductor composition, the composition is only required to have a viscosity adequate for coating, and the solid content concentration is not particularly limited.

The thermoelectric element layer including the thermoelectric semiconductor composition is not limited, and can be obtained by coating the thermoelectric semiconductor composition onto a substrate to form a coating film, and drying the coating film.

Examples of the method of coating the thermoelectric semiconductor composition onto the substrate to obtain a thermoelectric element layer include known methods such as screen printing, flexographic printing, gravure printing, spin coating, dip coating, die coating, spray coating, bar coating, and doctor blade coating. When forming a coating film in a pattern, a screen printing method, a slot die coating method, or the like, which can easily form a pattern using a screen plate having a desired pattern, are preferably used.

The resulting coating film is then dried to form a thermoelectric element layer. As the drying method, a well-known drying method can be used, such as hot air drying, heated roll drying, and infrared irradiation. The heating temperature is typically from 80 to 150° C., and while the heating time differs depending on the heating method, the heating time is typically from a few seconds to tens of minutes.

Furthermore, when a solvent is used in the preparation of the thermoelectric semiconductor composition, the heating temperature is not particularly limited as long as the temperature is within a temperature range in which the solvent that is used can be dried.

The thickness of the thermoelectric element layer is not limited, and is preferably from 100 nm to 1000 μm, more preferably from 300 nm to 600 μm, and even more preferably from 5 to 400 μm, from the perspectives of thermoelectric performance and film strength.

The thermoelectric element layer as a thin film including the thermoelectric semiconductor composition is preferably further subjected to an annealing treatment (hereinafter, sometimes referred to as “annealing treatment B”). By subjecting the thermoelectric element layer to the annealing treatment B, the thermoelectric performance can be stabilized, crystal growth of the thermoelectric semiconductor particles in the thin film can be promoted, and the thermoelectric performance can be further improved. The annealing treatment B is not particularly limited, but is ordinarily implemented in an atmosphere with the gas flow rate controlled, including in an inert gas atmosphere such as nitrogen or argon or in a reducing gas atmosphere, or is implemented under vacuum conditions, and while dependent on factors such as the heat resistance temperatures of the resin and ionic compound that are used, the annealing treatment B is typically implemented at a temperature of from 100 to 500° C. for several minutes to several tens of hours. Furthermore, in the annealing treatment B, the thermoelectric semiconductor composition may be pressed to increase the density of the thermoelectric semiconductor composition.

### Electrode

The thermoelectric conversion module according to the present invention includes the first electrode and the second electrode (hereinafter, may be simply referred to as “electrodes”).

The electrodes are preferably formed of at least one film selected from the group consisting of a vapor deposition film, a plated film, a conductive composition, and a metal foil.

Metal materials used in the electrodes are not particularly limited, and examples thereof include copper, gold, nickel, aluminum, rhodium, platinum, chromium, palladium, stainless steel, molybdenum, solder, or an alloy containing any of these metals.

Examples of methods for forming the electrodes include a method in which an electrode having no pattern formed is provided, and then processed into predetermined pattern shapes by a known physical treatment mainly using a photolithography method or chemical treatment, or a combination thereof, or a method in which patterns of electrodes are directly formed by screen printing, an inkjet method, or the like using conductive paste formed from a conductive composition including the metal materials and the like.

Examples of methods for forming an electrode having no pattern formed thereon include dry processes including physical vapor deposition (PVD) methods, such as vacuum vapor deposition, sputtering, and ion plating or chemical vapor deposition (CVD) methods, such as thermal CVD and atomic layer deposition (ALD); or wet processes including various coating methods, such as dip coating, spin coating, spray coating, gravure coating, die coating, and doctor blade coating, and electrodeposition methods; silver salt methods; electrolytic plating; electroless plating; and layering of metal foils. The method is appropriately selected according to the material for the electrode. In the layering of the metal foils, the metal foils may be joined to a thermoelectric material or the like by using a solder material.

From the perspective of maintaining thermoelectric performance, the electrodes used in the present invention are required to exhibit high electrical conductivity and high thermal conductivity, and therefore use of electrodes formed by a plating method or a vacuum film formation method is more preferable. Since high electrical conductivity and high thermal conductivity can be easily achieved, vacuum film formation methods such as vacuum vapor deposition and sputtering, electrolytic plating; and electroless plating are preferred. A pattern can be easily formed through a hard mask such as a metal mask depending on the dimensions of the pattern to be formed and the required dimensional accuracy.

The thicknesses of the respective layers of the electrodes are preferably from 10 nm to 200 μm, more preferably from 30 nm to 150 μm, and even more preferably from 50 nm to 120 μm. When the thicknesses of the respective layers of the electrodes are within the range described above, electrical conductivity is high, resistance is low, and sufficient strength as electrodes is obtained.

### Solder Layer

In the thermoelectric conversion module according to the present invention, a solder layer made of a solder material may be used for bonding the electrodes to the P-type thermoelectric element layer and the N-type thermoelectric element layer.

The solder material is not particularly limited, but from the perspective of being lead free and/or cadmium free, examples of solder materials having a relatively low melting point include Sn—In-based In52Sn48 [melting temperature: solidus temperature (approximately 119° C.), liquidus temperature (approximately 119° C.)], Sn—Bi-based Bi58Sn42 [melting temperature: solidus temperature (approximately 139° C.), liquidus temperature (approximately 139° C.)], Sn—Zn—Bi-based Sn89Zn8Bi3 [melting temperature: solidus temperature (approximately 190° C.), liquidus temperature (approximately 196° C.)], and Sn—Zn-based Sn91Zn9 [melting temperature: solidus temperature (approximately 198° C.), liquidus temperature (approximately 198° C.)].

Furthermore, from the perspective of being lead free and/or cadmium free, examples of solder materials having a relatively high melting point include Sn—Sb-based Sn95Sb5 [melting temperature: solidus temperature (approximately 238° C.), liquidus temperature (approximately 241° C.)], Sn—Cu based Sn99.3Cu0.7 [melting temperature: solidus temperature (approximately 227° C.), liquidus temperature (approximately 228° C.)], Sn—Cu—Ag-based Sn99Cu0.7Ag0.3 [melting temperature: solidus temperature (approximately 217° C.), liquidus temperature (approximately 226° C.)], Sn—Ag-based Sn97Ag3 [melting temperature: solidus temperature (approximately 221° C.), liquidus temperature (approximately 222° C.)], Sn—Ag—Cu-based Sn96.5Ag3Cu0.5 [melting temperature: solidus temperature (approximately 217° C.), liquidus temperature (approximately 219° C.)] and Sn95.5Ag4Cu0.5 [melting temperature: solidus temperature (approximately 217° C.), liquidus temperature (approximately 219° C.)], and Sn—Ag—Cu-based Sn95.8Ag3.5Cu0.7 [melting temperature: solidus temperature (approximately 217° C.), liquidus temperature (approximately 217° C.)].

In consideration of heat resistance of the substrates, the electrodes, and the like included in the thermoelectric conversion module, the above solder materials can be used as appropriate.

The thickness of the solder layer containing the solder material (after heating and cooling) is preferably from 10 to 200 μm, more preferably from 30 to 130 μm, and particularly preferably from 40 to 120 μm. When the thickness of the solder layer is within this range, bondability with the thermoelectric element layer and the electrode are easily obtained.

Examples of the method of coating a substrate with the solder material include known methods such as stencil printing, screen printing, and dispensing methods. The heating temperature varies depending on the solder material used, the substrate, and the like. Heating is typically performed at 100 to 280° C. for 0.5 to 20 minutes.

Examples of commercially available solder material products that can be used include the following. For example, a 42Sn/58Bi alloy [available from Tamura Corporation, product name: SAM10-401-27, melting temperature: solidus temperature (approximately 139° C.), liquidus temperature (approximately 139° C.)], a 96.5Sn3.0Ag0.5Cu alloy [available from NIHON HANDA Co., Ltd., product name: PF305-153TO, melting temperature: solidus temperature (approximately 217° C.), liquidus temperature (approximately 219° C.)], and a Sn/57Bi alloy [available from NIHON HANDA Co., Ltd., product name: PF141-LT7HO, melting temperature: solidus temperature (approximately 137° C.)] can be used.

### Heat Dissipation Layer

A heat dissipation layer may be used in the thermoelectric conversion module according to the present invention. The heat dissipation layer is placed on the first substrate and/or the second substrate of the thermoelectric conversion module.

Preferably, the thermoelectric conversion module includes a first heat dissipation layer on the first principal surface of the first substrate and a second heat dissipation layer on the fourth principal surface of the second substrate.

For example, in FIG. 2, the first heat dissipation layer 9a and the second heat dissipation layer 9b are provided on the first principal surface 1a and the fourth principal surface 2b in this order.

Examples of materials for each of the first heat dissipation layer and the second heat dissipation layer include metal materials, ceramic materials, or mixtures of these materials and resins. Among these, at least one material selected from metal materials and ceramic materials is preferable.

Examples of the metal materials include: a single metal such as gold, silver, copper, nickel, tin, iron, chromium, platinum, palladium, rhodium, iridium, ruthenium, osmium, indium, zinc, molybdenum, manganese, titanium, and aluminum; and an alloy containing two or more metals such as stainless steel and brass.

Examples of the ceramic materials include barium titanate, aluminum nitride, boron nitride, aluminum oxide, silicon carbide, and silicon nitride.

Among these, the metal materials are preferred from the perspectives of high thermal conductivity, processability, and flexibility. Among the metal materials, copper (including oxygen-free copper) and stainless steel are preferable, and copper is more preferable because of its higher thermal conductivity and easier processability.

The resin to be mixed with the metal materials or the ceramic materials is not particularly limited, and examples thereof include polyimide, polyamide, polyamide-imide, polyphenylene ether, polyether ketone, polyether ether ketone, polyolefin, polyester, polycarbonate, polysulfone, polyethersulfone, polyphenylene sulfide, polyarylate, nylon, acrylic resin, cycloolefin polymer, and aromatic polymer.

Typical examples of the metal materials having high thermal conductivity used in the present invention are described below.

### Oxygen-Free Copper

Oxygen-free copper (OFC) generally refers to high-purity copper of 99.95% (3N) or more that does not contain oxides. The Japanese Industrial Standards specifies oxygen-free copper (JIS H 3100, C1020) and oxygen-free copper for electron tubes (JIS H 3510, C1011).

### Stainless Steel (JIS)

SUS304: 18Cr-8Ni (containing 18% Cr and 8% Ni)
SUS316: 18Cr-12Ni (stainless steel containing 18% Cr, 12% Ni, and molybdenum (Mo))

The method for forming the heat dissipation layer used in the present invention is not particularly limited, and examples thereof include a method for processing a sheet heat dissipation layer to have predetermined dimensions, and a method for processing a heat dissipation layer into a predetermined pattern shape by a known physical treatment mainly using a photolithography method or chemical treatment, or a combination thereof in advance.

The thermal conductivity of the heat dissipation layer is preferably from 15 to 500 W/(m·K), more preferably from 100 to 450 W/(m·K), and even more preferably from 250 to 420 W/(m·K). When the thermal conductivity of the heat dissipation layer is in the above-described range, a temperature difference can be efficiently provided.

The thickness of the heat dissipation layer is preferably from 15 to 550 μm, more preferably from 70 to 510 μm. When the thickness of the heat dissipation layer is in this range, for example, a temperature difference can be efficiently provided in the thickness direction of the P-type thermoelectric element layer and the N-type thermoelectric element layer.

In the thermoelectric conversion module according to the present invention, since the thermistor for temperature detection is embedded inside the substrate included in the thermoelectric conversion module, the thermoelectric conversion module can be made thinner.

### Method for Manufacturing Thermoelectric Conversion Module

A method for manufacturing a thermoelectric conversion module of the present invention, the thermoelectric conversion module including a first substrate having a first principal surface and a second principal surface opposite to the first principal surface, a second substrate having a third principal surface facing the second principal surface and a fourth principal surface opposite to the third principal surface, a first electrode provided on the second principal surface, a second electrode provided on the third principal surface, a P-type thermoelectric element layer and an N-type thermoelectric element layer sandwiched between the first electrode and the second electrode and arrayed along the second principal surface and the third principal surface, and a thermistor for temperature detection, the thermistor being embedded inside the first substrate and/or the second substrate, in which current-carrying electrodes configured to energize the thermistor are located on at least one of the first principal surface, the second principal surface, the third principal surface, or the fourth principal surface, the method includes preferably (M) electrically connecting the second electrode to the P-type thermoelectric element layer and the N-type thermoelectric element layer on the first electrode provided on the second principal surface of the first substrate using the second substrate having the thermistor for temperature detection embedded therein and including the second electrode provided on the third principal surface, or preferably (N) electrically connecting the first electrode to the P-type thermoelectric element layer and the N-type thermoelectric element layer on the second electrode provided on the third principal surface of the second substrate using the first substrate having the thermistor for temperature detection embedded therein and including the first electrode provided on the second principal surface.

The method for manufacturing a thermoelectric conversion module according to the present invention will be described below using the drawings.

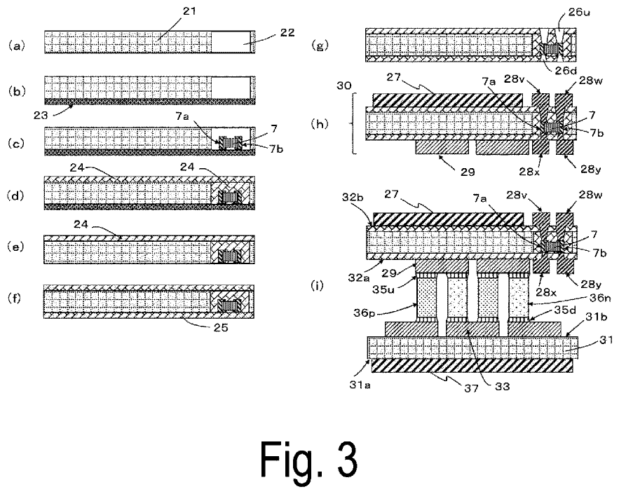

FIG. 3 is an explanatory diagram illustrating an example of steps of a method for manufacturing the thermoelectric conversion module according to the present invention in the order of the steps. (a) is a cross-sectional configuration view after forming a through-hole 22 inside a substrate 21, (b) is a cross-sectional configuration view after forming a pressure sensitive adhesive tape 23 on a lower surface of the substrate 21, (c) is a cross-sectional configuration view after providing the thermistor 7 with the terminal electrode 7a and the terminal electrode 7b at both ends in the through-hole 22 in the substrate 21, (d) is a cross-sectional configuration view after providing an insulating material layer 24 in the through-hole 22 and on an upper surface of the substrate 21, (e) is a cross-sectional configuration view after peeling off the pressure sensitive adhesive tape 23 from the lower surface of the substrate 21, (f) is a cross-sectional configuration view after providing an insulating material layer 25 on the lower surface of the substrate 21, (g) is a cross-sectional configuration view after forming a hole 26u from an upper surface of the insulating material layer 24 to upper surfaces of the terminal electrode 7a and the terminal electrode 7b of the thermistor 7, and a hole 26d from a lower surface of the insulating material layer 25 to lower surfaces of the terminal electrode 7a and the terminal electrode 7b of the thermistor 7, and (h) is a cross-sectional configuration view after forming current-carrying electrodes 28v, 28w, 28x, and 28y formed from copper layers, and simultaneously forming a second heat dissipation layer 27 on the upper surface of the insulating material layer 24 and a second electrode 29 on the lower surface of the insulating material layer 25, by forming metal material layers, for example, preferably copper layers, inside the hole 26u and the hole 26d formed in (g) and on the surfaces of the insulating material layer 24 and the insulating material layer 25. Note that the current-carrying electrodes may be located only on one side of the substrate 21, such as the current-carrying electrodes 28v and 28w, or may be located only on the other side of the substrate 21, such as the current-carrying electrodes 28x and 28y.

Next, (i) is a cross-sectional configuration view of the thermoelectric conversion module after electrically connecting the second electrode 29 provided on a thermistor-embedded substrate 30 obtained in (h) to surfaces of a P-type thermoelectric element layer 36p and an N-type thermoelectric element layer 36n on a first electrode 33 provided on a second principal surface 31b of a first substrate 31 including a first heat dissipation layer 37 on a first principal surface 31a. Note that 32a indicates a third principal surface, 32b indicates a fourth principal surface, and 35u and 35d indicate solder layers.

Step (M) or step (N) preferably includes the following steps (S-1) to (S-3).
Step (S-1): a step of providing the through-hole in the first substrate and/or the second substrate
Step (S-2): a step of embedding the thermistor in the through-hole
Step (S-3): a step of providing the current-carrying electrodes to which the thermistor is to be connected on the first substrate and/or the second substrate

### Step (S-1): Through-Hole Forming Step

Step (S-1) is a step of forming the through-hole inside the substrate included in the thermoelectric conversion module, and is a step of forming the through-hole in the first substrate and/or the second substrate.

A known method can be used to form the through-hole and there are no limitations. Examples include laser processing and a method using a drill.

### Step (S-2) Thermistor Embedding Step

Step (S-2) is a step of embedding the thermistor inside the substrate included in the thermoelectric conversion module, and is a step of placing the thermistor inside the through-hole in the first substrate and/or the second substrate formed in step (S-1).

A known method can be used for placing the thermistor, and there are no limitations. For example, there is a method that involves sealing the thermistor in which the substrate is temporarily fixed by layering a pressure sensitive adhesive tape on a lower surface of the substrate, placing the thermistor on the pressure sensitive adhesive tape, and filling the entire through-hole including the thermistor with an insulating material such as a resin.

### Step (S-3) Current-Carrying Electrode Forming Step

Step (S-3) is a step of forming current-carrying electrodes that energize the thermistor on a surface of the substrate included in the thermoelectric conversion module, and is a step of forming the current-carrying electrodes on the surface of the first substrate and/or the second substrate via wiring layers from terminal electrodes at both ends of the thermistor in the through-hole in the first substrate and/or the second substrate sealed in step (S-2).

A known method can be used to form the current-carrying electrodes, and there are no limitations. For example, there is a method in which holes are formed from the surfaces of the first substrate and/or the second substrate to terminal electrode portions at both ends of the thermistor by laser processing, the above-described metal material is deposited in the holes and on the surfaces of the first substrate and/or the second substrate by, for example, plating or vapor deposition, and then the metal material layers formed on the surfaces are formed into predetermined electrode patterns by photolithography or the like.

Step (M) or step (N) further preferably includes any one of steps (S-4) to (S-6).

### Step (S-4) Electrode Forming Step

Step (S-4) is a step of forming electrodes included in the thermoelectric conversion module. To be specific, step (S-4) is a step of providing a second electrode on a third principal surface of the second substrate, and a step of providing a first electrode on a second principal surface of the first substrate.

The electrodes can be formed on the second principal surface of the first substrate and the third principal surface of the second substrate by the above-described forming method using the above-described metal material used for the electrodes.

Further, from the viewpoint of bonding with the thermoelectric element layer, step (S-4) preferably includes a step of forming solder layers as bonding layers on the obtained electrodes.

The solder layers can be formed on the first electrode and the second electrode by the above-described forming method using the above-described solder material.

Note that the solder layers may be formed on the P-type thermoelectric element layer and the N-type thermoelectric element layer.

### Step (S-5) Thermoelectric Element Layer Forming Step

Step (S-5) is a step of forming thermoelectric element layers included in the thermoelectric conversion module. To be specific, step (S-5) is a step of providing the P-type thermoelectric element layer and the N-type thermoelectric element layer on the first electrode on the second principal surface of the first substrate, or a step of providing the P-type thermoelectric element layer and the N-type thermoelectric element layer on the second electrode on the third principal surface of the second substrate.

The P-type thermoelectric element layer and the N-type thermoelectric element layer can be formed, for example, on the first electrode on the second principal surface of the first substrate or on the second electrode on the third principal surface of the second substrate by the above-described forming method using, for example, the above-described thermoelectric semiconductor composition.

### Step (S-6) Thermoelectric Conversion Module Assembly Step

Step (S-6) is a step of assembling the thermoelectric conversion module by electrically connecting the second electrode on the third principal surface of the second substrate obtained in step (S-4) to the P-type thermoelectric element layer and the N-type thermoelectric element layer on the first electrode on the second principal surface of the first substrate obtained in step (S-5), or a step of assembling the thermoelectric conversion module by electrically connecting the first electrode on the second principal surface of the first substrate obtained in step (S-4) to the P-type thermoelectric element layer and the N-type thermoelectric element layer on the second electrode on the third principal surface of the second substrate obtained in step (S-5).

A known method can be used to assemble the thermoelectric conversion module by electrically connecting the electrodes to surfaces of the P-type thermoelectric element layer and the N-type thermoelectric element layer.

A heat dissipation layer forming step may be further included after step (S-3) and/or after step (S-6).

The heat dissipation layer forming step is, for example, a step of providing the second heat dissipation layer on the fourth principal surface of the second substrate included in the thermoelectric conversion module and/or a step of providing the first heat dissipation layer on the first principal surface of the first substrate included in the thermoelectric conversion module.

The formation of the heat dissipation layer is not limited, and examples thereof include, as described above, a method for processing a sheet heat dissipation layer to have predetermined dimensions, and a method for processing a heat dissipation layer into a predetermined pattern shape by a known physical treatment mainly using a photolithography method or chemical treatment, or a combination thereof in advance.

With the manufacturing method according to the present invention, it is possible to manufacture a thin thermoelectric conversion module in which a thermistor for temperature detection is embedded inside a substrate included in the thermoelectric conversion module.

### INDUSTRIAL APPLICABILITY

With the thermoelectric conversion module according to the present invention, it is expected that a known thermoelectric conversion module can be made thinner, lighter, and smaller.

### REFERENCE SIGNS LIST

1, 31: First substrate
1a, 31a: First principal surface
1b, 31b: Second principal surface
2, 32: Second substrate
2a, 32a: Third principal surface
2b, 32b: Fourth principal surface
3, 33: First electrode
4, 29: Second electrode
5u, 5d, 35u, 35d: Solder layer
6p, 36p: P-type thermoelectric element layer
6n, 36n: N-type thermoelectric element layer
7: Thermistor
7a: Terminal electrode
7b: Terminal electrode
8v, 8w: Current-carrying electrode (fourth principal surface)
8x, 8y: Current-carrying electrode (third principal surface)
9a, 37: First heat dissipation layer
9b, 27: Second heat dissipation layer
11, 12: Thermoelectric conversion module
21: Substrate
22: Through-hole
23: Pressure sensitive adhesive tape
24, 25: Insulating material layer
26u, 26d: Hole
28v, 28w: Current-carrying electrode
28x, 28y: Current-carrying electrode
30: Thermistor-embedded substrate

1. A thermoelectric conversion module comprising:
a first substrate having a first principal surface and a second principal surface opposite to the first principal surface;
a second substrate having a third principal surface facing the second principal surface and a fourth principal surface opposite to the third principal surface;
a first electrode provided on the second principal surface;
a second electrode provided on the third principal surface;
a P-type thermoelectric element layer and an N-type thermoelectric element layer sandwiched between the first electrode and the second electrode and arrayed along the second principal surface and the third principal surface; and
a thermistor for temperature detection, the thermistor being embedded inside the first substrate and/or the second substrate, wherein
current-carrying electrodes configured to energize the thermistor are located on at least one of the first principal surface, the second principal surface, the third principal surface, or the fourth principal surface.

2. The thermoelectric conversion module according to claim 1, further comprising:
a first heat dissipation layer on the first principal surface of the first substrate; and
a second heat dissipation layer on the fourth principal surface of the second substrate.

3. The thermoelectric conversion module according to claim 1, wherein
the current-carrying electrodes are located on the first principal surface of the first substrate or the fourth principal surface of the second substrate, and are provided as a pair of electrodes spaced apart from each other.

4. The thermoelectric conversion module according to claim 1, wherein
the thermistor and the current-carrying electrodes are connected along a thickness direction of the first substrate or the second substrate.

5. The thermoelectric conversion module according to claim 1, wherein
the first substrate and the second substrate are made of insulating materials.

6. A method for manufacturing a thermoelectric conversion module,
the thermoelectric conversion module including a first substrate having a first principal surface and a second principal surface opposite to the first principal surface,
a second substrate having a third principal surface facing the second principal surface and a fourth principal surface opposite to the third principal surface,
a first electrode provided on the second principal surface,
a second electrode provided on the third principal surface,
a P-type thermoelectric element layer and an N-type thermoelectric element layer sandwiched between the first electrode and the second electrode and arrayed along the second principal surface and the third principal surface, and
a thermistor for temperature detection, the thermistor being embedded inside the first substrate and/or the second substrate, wherein
current-carrying electrodes configured to energize the thermistor are located on at least one of the first principal surface, the second principal surface, the third principal surface, or the fourth principal surface, the method comprising:
(M) electrically connecting the second electrode to the P-type thermoelectric element layer and the N-type thermoelectric element layer on the first electrode provided on the second principal surface of the first substrate using the second substrate including the second electrode provided on the third principal surface; or
(N) electrically connecting the first electrode to the P-type thermoelectric element layer and the N-type thermoelectric element layer on the second electrode provided on the third principal surface of the second substrate using the first substrate including the first electrode provided on the second principal surface.

7. The method for manufacturing a thermoelectric conversion module according to claim 6, wherein
(M) or (N) includes the following (S-1) to (S-3):
(S-1): providing a through-hole in the first substrate and/or the second substrate
(S-2): embedding the thermistor in the through-hole
(S-3): providing the current-carrying electrodes to which the thermistor is to be connected on the first substrate and/or the second substrate.
